(19) United States
(12) Patent Application Publication
(10) Pub. No.: US 2025/0246414 A1
(43) Pub. Date: Jul. 31, 2025

(54) SYSTEMS AND METHODS FOR HIGH-THROUGHPUT ANGLED ION PROCESSING

(71) Applicant: Applied Materials, Inc., Santa Clara, CA (US)

(72) Inventors: Alexandre LIKHANSKII, Malden, MA (US); Costel BILOIU, Rockport, MA (US); Russell Chin Yee TEO, Palo Alto, CA (US); Christopher CAMPBELL, Newburyport, MA (US)

(73) Assignee: Applied Materials, Inc., Santa Clara, CA (US)

(21) Appl. No.: 18/424,470

(22) Filed: Jan. 26, 2024

(51) Int. Cl. H01J 37/32

(52) U.S. Cl. CPC H01J 37/32623; H01J 37/32733; H01J 37/3211

(57) ABSTRACT

Disclosed herein are systems and methods for high throughput angled ion processing. In one approach, a processing apparatus may include a chamber operable to contain a plasma, the chamber defined by a plurality of sidewalls, a first end wall, and a second end wall opposite the first end wall, an extraction assembly coupled to the second end wall, the extraction assembly comprising a plurality of apertures, wherein ions are extracted through the plurality of apertures are delivered to a substrate at a non-zero angle relative to a perpendicular extending from the substrate, and wherein the substrate is positioned external to the chamber. The processing apparatus may further include an actuator operable to shift the substrate relative to the moveable plates as the ions are extracted through the plurality of apertures.

### FIELD OF THE DISCLOSURE

Embodiments of the present disclosure relate to an apparatus and method for extracting an angled ion beam from a plasma chamber and, more particularly, to an apparatus and method for extracting a low-energy, high-current angled ion beam.

### BACKGROUND OF THE DISCLOSURE

Recently, there has been a transition to create three-dimensional devices in the semiconductor industry. To process these three-dimensional devices, angled ion implants are often used. Angled ion implants refer to those ion beams which strike the substrate at a non-zero angle. Angled ion beams have many applications. For example, angled ion beams may be used to implant a sidewall of a fin structure or a trench, or may be used for etching processes, deposition processes, and other applications.

One way to perform these angled ion implants is to rotate or tilt the platen on which the substrate is disposed. In other words, the ion beam is generated in the traditional manner, but the platen is tilted so that the ion beam strikes the substrate at a non-zero angle. This approach may allow the generation of an ion beam which strikes the substrate at an angle of 20° or more. One shortcoming with this approach is that the various regions of the substrate are at different distances from the ion beam source. For example, by tilting, several regions of the substrate will be closer to the ion beam source than other regions. This may cause process variations across the substrate.

Another approach is to rotate the ion beam source with respect to the substrate to achieve the desired angle of the extracted ion beam. This approach has similar shortcomings as the previously described method of tilting the substrate.

Yet another approach is to control and vary the shape of the plasma sheath to vary the angle of the ions extracted from a plasma processing chamber. However, this approach may have limitations in terms of the amount of current that may be extracted.

Therefore, it would be advantageous if there was a system for generating a high-current, low-energy angled ion beam that does not suffer from these limitations.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a processing apparatus may include a chamber operable to contain a plasma, the chamber defined by a plurality of sidewalls, a first end wall, and a second end wall opposite the first end wall, an extraction assembly coupled to the second end wall, the extraction assembly comprising a plurality of blockers partially covering an opening through the second end wall, wherein ions are extracted through the opening and delivered to a substrate at a non-zero angle relative to a perpendicular extending from the substrate, and wherein the substrate is positioned external to the chamber. The processing apparatus may further include an actuator operable to dither the substrate relative to the fixed or moveable plates as the ions are extracted through the opening.

In another aspect, a plasma processing apparatus may include a plasma chamber operable to contain a plasma, the plasma chamber defined by a plurality of sidewalls, a first end wall, and a second end wall opposite the first end wall, and an extraction assembly coupled to the second end wall, the extraction assembly including an extraction plate having a plurality of blockers partially covering an opening of the second end wall. Ions are extracted through the plurality of blockers and delivered to a substrate at a non-zero angle relative to a perpendicular extending from the substrate, wherein the substrate is positioned external to the plasma chamber. The plasma processing apparatus may further include an actuator operable to dither the substrate relative to extraction plate as the ions are extracted through the plurality of blockers.

In yet another aspect, a method may include generating a plasma within a plasma chamber, wherein the chamber is defined by a plurality of sidewalls, a first end wall, and a second end wall opposite the first end wall, and arranging an extraction assembly along the second end wall, the extraction assembly including an extraction plate having plurality of blockers partially covering an opening of the second end wall. The method may further include extracting ions through the plurality of blockers, delivering the ions to a substrate at a non-zero angle relative to a perpendicular extending from a plane defined by a top surface of the substrate, wherein the substrate is positioned external to the plasma chamber, and dithering the substrate relative to the extraction plate as the ions are delivered to the substrate.

### BRIEF DESCRIPTION OF THE DRAWINGS

The accompanying drawings illustrate exemplary approaches of the disclosure, including the practical application of the principles thereof, as follows:

FIG. 1 is a schematic cross-sectional view of a processing apparatus including an exemplary plasma processing chamber according to one or more embodiments;

FIG. 2 is cross-sectional view of an exemplary plasma processing chamber according to one or more embodiments;

FIG. 3 is a perspective view of an extraction plate and wafer according to one or more embodiments;

FIG. 4 is a side view of an extraction assembly according to one or more embodiments;

FIG. 5 is a schematic top plan view of an exemplary cluster processing system according to one or more embodiments; and

FIG. 6 depicts a flow diagram illustrating a process for ion processing according to one or more embodiments.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and apparatuses in accordance with the present disclosure will now be described more fully hereinafter with reference to the accompanying drawings, where various embodiments are shown. The methods systems, and apparatuses may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments of the present disclosure advantageously provide wafer dithering along with pulse duty cycle correction for high-throughput uniform processing without overscanning. Directional deposition of a material is also contemplated in some embodiments.

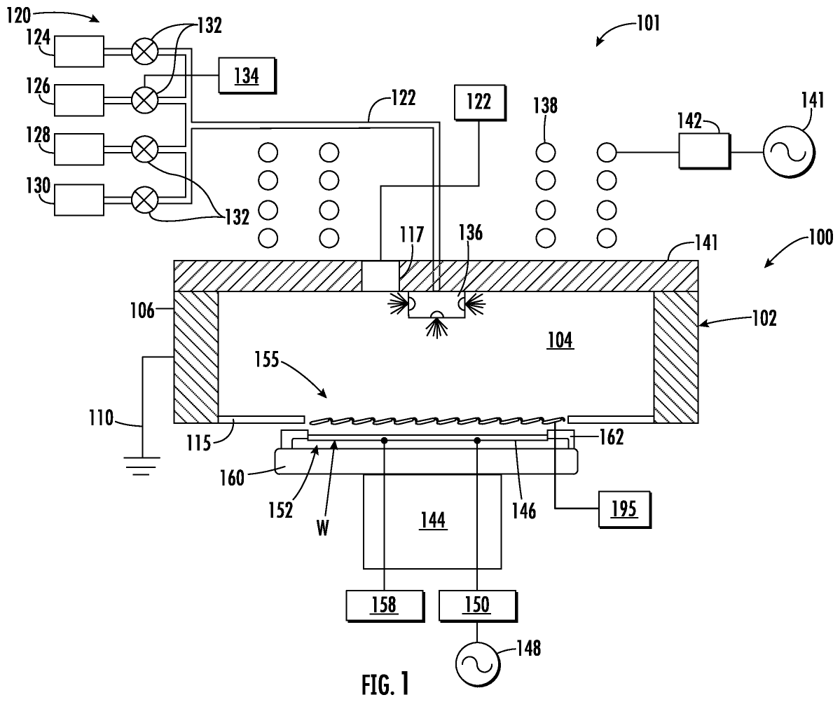

FIG. 1 is a schematic cross-sectional view of a processing apparatus 101 including an exemplary plasma processing chamber 100 suitable for performing a patterning process. One example of the plasma processing chamber 100 is a Centura® Sculpta® patterning chamber, available from Applied Materials, Inc., located in Santa Clara, CA. It is contemplated that other process chambers, including those from other manufactures, may be adapted to practice embodiments of the disclosure. It will be further contemplated that the components of the processing apparatus 101 are not necessarily to scale. The drawings are merely representations, not intended to portray specific parameters of the disclosure.

The plasma processing chamber 100 includes a chamber body 102 having a chamber volume 104 defined therein. The chamber body 102 has sidewalls 106, a first end wall 114, and a second end wall 115, wherein any of the sidewalls 106, the first end wall 114, or the second end wall 115 may be coupled to ground 110. Although non-limiting, the chamber body 102 may be cylindrical. In some embodiments, the sidewalls 106 may have a liner to protect the sidewalls 106 and extend the time between maintenance cycles of the plasma processing chamber 100. The chamber body 102 may support the first end wall 114, which encloses the chamber volume 104. The chamber body 102 may be fabricated from aluminum or other suitable materials. The dimensions of the chamber body 102 and related components of the plasma processing chamber 100 are not limited and generally are proportionally larger than the size of a substrate W to be processed therein. Although non-limiting, examples of substrate sizes include 166 mm diameter, 250 mm diameter, 300 mm diameter and 450 mm diameter, among others.

In some embodiments, a pumping port (not shown) may be formed through the sidewall 106 of the chamber body 102 and connected to the chamber volume 104, while a pumping device (not shown) may be coupled through the pumping port to the chamber volume 104 to evacuate and control the pressure therein. The pumping device may include one or more pumps and throttle valves.

A gas panel 120 may be coupled by a gas line 122 to the chamber body 102 to supply process gases into the chamber volume 104. The gas panel 120 may include one or more process gas sources 124, 126, 128, 130 and may additionally include inert gases, non-reactive gases, and reactive gases, if desired. Examples of process gases that may be provided by the gas panel 120 include, but are not limited to, hydrocarbon containing gas including methane (CH₄), sulfur hexafluoride (SF₆), silicon chloride (SiCl₄), carbon tetrafluoride (CF₄), hydrogen bromide (HBr), hydrocarbon containing gas, argon gas (Ar), chlorine (Cl₂), nitrogen (N₂), helium (He) and oxygen gas (O₂). Additionally, process gases may include nitrogen, chlorine, fluorine, oxygen and hydrogen containing gases such as BC₁₃, C₂F₄, C₄F₈, C₄F₆, CHF₃, CH₂F₂, CH₃F, NF₃, NH₃, CO₂, SO₂, CO, N₂, NO₂, N₂O, H₂, among others.

Valves 132 control the flow of the process gases from the process gas sources 124, 126, 128, 130 from the gas panel 120 and are managed by a controller 134. The flow of the gases supplied to the chamber body 102 from the gas panel 120 may include combinations of the gases.

The first end wall 114 may include a nozzle 136, wherein the nozzle 136 has one or more ports for introducing the process gases from the process sources 124, 126, 128, 130 of the gas panel 120 into the chamber volume 104. After the process gases are introduced into the plasma processing chamber 100, the gases are energized to form plasma. An antenna 138, such as one or more inductor coils, may be provided adjacent to the plasma processing chamber 100. An antenna power supply 141 may power the antenna 138 through a match circuit 142 to inductively couple energy, such as RF energy, to the process gas to maintain a plasma formed from the process gas in the chamber volume 104 of the plasma processing chamber 100. Alternatively, or in addition to the antenna power supply 141, process electrodes below the substrate W and/or above the substrate W may be used to capacitively couple RF power to the process gases to maintain the plasma within the chamber volume 104. The operation of the antenna power supply 141 may be controlled by a controller, such as controller 134, that also controls the operation of other components in the plasma processing chamber 100.

A platen or substrate support pedestal 144 is disposed below/adjacent the second end wall 115 to support the substrate W during processing. The substrate support pedestal 144 may include an electrostatic chuck (ESC) 146 for holding the substrate W during processing, wherein the ESC 146 uses the electrostatic attraction to hold the substrate W to the substrate support pedestal 144. The ESC 146 may be powered by a pulsed DC power supply 148 integrated with a match circuit 150. In some embodiments, the ESC 146 may be further powered by a secondary, RF power supply. The ESC 146 comprises an electrode 152 embedded within a dielectric body. The electrode 152 is coupled to the DC power supply 148 and provides a bias which attracts plasma ions, formed by the process gases in the chamber volume 104, to the ESC 146 and substrate W positioned thereon. The DC power supply 148 may cycle on and off, or pulse, during processing of the substrate W. In some embodiments, the ESC 146 may have an isolator (not shown) for the purpose of making the sidewall of the ESC 146 less attractive to the plasma to prolong the maintenance life cycle of the ESC 146.

In some embodiments, the electrode 152 may be coupled to a power source 158. The power source 158 provides a chucking voltage of about 166 volts to about 1660 volts to the electrode 152. The power source 158 may also include a system controller for controlling the operation of the electrode 152 by directing a DC current to the electrode 152 for chucking and de-chucking the substrate W.

The ESC 146 may include one or more temperature controllers disposed therein and connected to a power source (not shown), for heating or cooling the substrate. For example, a cooling base 160 supporting the ESC 146 may include conduits for circulating a heat transfer fluid to maintain a temperature of the ESC 146 and substrate W disposed thereon. The ESC 146 is configured to perform in the temperature range required by the thermal budget of the device being fabricated on the substrate W. For example, the ESC 146 may be configured to maintain the substrate W at a temperature of about 25 degrees Celsius to about 500 degrees Celsius for certain embodiments.

A shield or cover ring 162 is disposed on the ESC 146 and along the periphery of the substrate support pedestal 144. The cover ring 162 is configured to confine etching gases to a desired portion of the exposed top surface of the substrate W, while shielding the top surface of the substrate support pedestal 144 from the plasma environment inside the plasma processing chamber 100. In some embodiments, the cover ring 162 may be powered by one or more power sources, such as the power source 158. Lift pins (not shown) may be selectively moved through the substrate support pedestal 144 to lift the substrate W above the substrate support pedestal 144 to facilitate access to the substrate W by a transfer robot (not shown) or other suitable transfer mechanism.

The controller 134 may be utilized to control the process sequence, regulating the gas flows from the gas panel 120 into the plasma processing chamber 100 and other process parameters. Software routines, when executed by the controller 134, transform the controller 134 into a specific purpose computer (controller) that controls the plasma processing chamber 100 such that the processes are performed in accordance with the present disclosure. The software routines may also be stored and/or executed by a second controller (not shown) that is collocated with the plasma processing chamber 100.

Adjacent the substrate W may be an extraction assembly 155. As will be described in greater detail herein, the extraction assembly 155 may include optics having a plurality of apertures that allow for angled extraction of an ion beam, which is directed to the substrate W. The optics may be biased at an extraction plate voltage, such as the extraction voltage or a different voltage through the use of an extraction plate power source/supply 195. In some embodiments, this extraction plate power supply 195 may be used to provide the extraction voltage to the plasma processing chamber 100. In other embodiments, the extraction plate power supply 195 may only be in communication with the optics. Further, although one extraction plate power supply 195 is illustrated, it is understood that multiple extraction plate power supplies may be used in any embodiment. Still furthermore, an extraction plate of the optics may be grounded while the substrate W is negatively biased. Thus, in certain embodiments, the extraction plate voltage may be equal to the extraction voltage. In other embodiments, the extraction plate voltage may be different than the extraction voltage. For example, in the case of a positive extraction voltage, the extraction plate voltage may be less positive than the extraction voltage.

In some embodiments, the extraction plate power supply 195 may be referenced to ground, the extraction voltage, or to the substrate W. If referenced to the extraction voltage, the extraction plate power supply 195 may supply a non-positive voltage, such as ground or a negative voltage. If the extraction plate power supply 195 is referenced to the substrate W, the extraction plate power supply 195 may supply a positive voltage. Embodiments are not limited in this context.

In some embodiments, the first end wall 114 may further include a window 117 that facilitates optical process monitoring. In one implementation, the window 117 is comprised of quartz or other suitable material that is transmissive to a signal utilized by an optical monitoring system 121 mounted outside the plasma processing chamber 100. In other embodiments, the optical monitoring system 121 may alternatively, or additionally, be positioned adjacent the substrate W, external to the chamber body 102.

The optical monitoring system 121 is positioned to view at least one of the interior chamber volume 104 and/or the substrate W and the extraction assembly 155. In one embodiment, the optical monitoring system 121 is coupled to the first end wall 114 and facilitates an integrated etch and/or deposition process that uses optical metrology to provide information that enables process adjustment to compensate for incoming substrate pattern feature inconsistencies (such as thickness, and the like), and provide process state monitoring (such as plasma monitoring, temperature monitoring, and the like) as needed. One optical monitoring system that may be adapted to benefit from the disclosure is the EyeD® full-spectrum, interferometric metrology module, available from Applied Materials, Inc., of Santa Clara, CA.

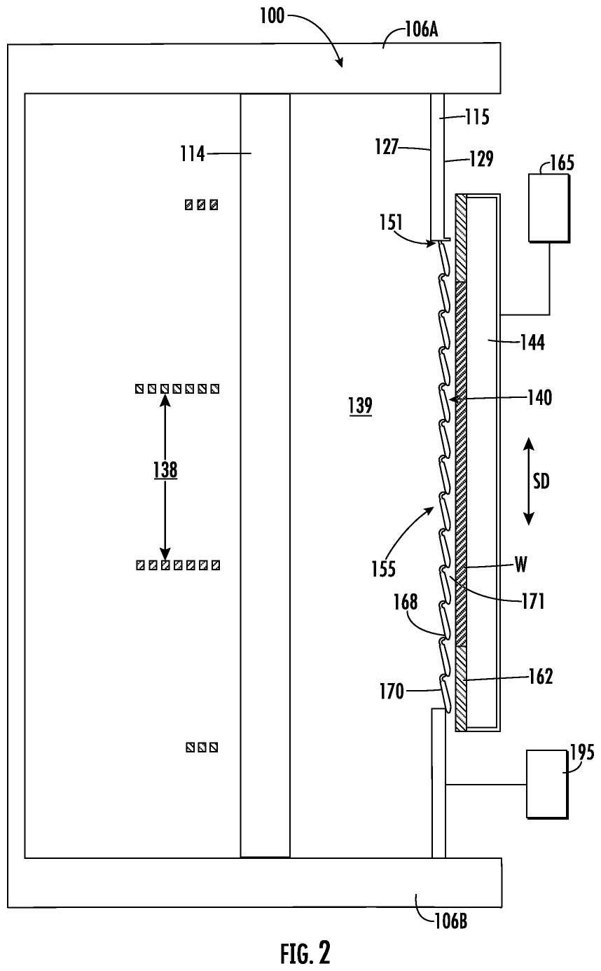

FIG. 2 shows an example of the plasma processing chamber 100 in greater detail. Only certain aspects of the chamber 100 are shown for ease of explanation. The chamber 100 may include the first end wall 114 opposite the second end wall 115. The extraction assembly 155 includes optics and an extraction plate 140 coupled to the second end wall 115 and located proximate the substrate W, wherein the extraction plate 140 includes apertures 168 that allow for angled extraction of ions 171, which are directed to the substrate W. The second end wall 115 may include an interior side 127 opposite an exterior side 129. As shown, plasma 139 may be enclosed, in part, by the interior side 127, while the exterior side 129 is directly adjacent the cover ring 162 and the substrate W. In some embodiments, the second end wall 115 may be connected to the sidewalls 106A, 106B and to the extraction plate 140. Although not limited to any particular number, in some embodiments, the extraction plate 140 may include one or more beam blockers 166 to cover an approximately 300 mm wafer and part of the shield ring 162.

During processing of the substrate W, plasma 139 is generated within the chamber 100, and the substrate support pedestal 144 may be moved or shifted relative to the extraction plate 140, e.g., in a shift direction ‘SD’. For example, the support pedestal 144 may be moved towards sidewall 106A and then towards sidewall 106B in an alternating, dithering cycle along a first direction as the plasma 139 is being generated and the ions 171 are being delivered to the substrate W. In other embodiments, the support pedestal 144 may be dithered back and forth in a second direction, which is perpendicular to the first direction. Either way, the substrate W remains generally aligned with opening 151 formed through/by the second end wall 115 throughout the cycle. This dithering, or back and forth (up and down in the orientation shown) movement of the substrate W relative to the extraction plate 140 between a first position and a second position, helps achieve a more uniform delivery of the ions 171 to the substrate W. As a result, all parts of the substrate W may receive a same exposure to the ion beam and radical flux.

As mentioned above, the substrate W and the substrate support pedestal 144 may be subjected to a DC (pulsed DC) or RF biasing during the ion process. Meanwhile, biasing the extraction plate 140 using the extraction plate power source/supply 195 may adjust the ion angle between 25 to 65 degrees, as desired. Changing the z-gap (e.g., distance between extraction plate 140 and the substrate W) may further enable even lower ion delivery angles in some embodiments. For example, a plasma deposition process may enable a liner to be formed, as desired, over the substrate W. The substrate support pedestal 144 may be moved using one or more electromechanical actuators 165 to achieve the dithering movement, although embodiments herein are not limited to any particular biasing device. Furthermore, it will be appreciated that the disclosure is not limited to the shown optics, but will work with optics of different shapes, sizes, materials, etc.

When the substrate W is being processed, the substrate W may be scanned across the opening 151, between the first position and the second position. When the substrate W reaches the end of a pass scan (e.g., first position), the ions 171 of the beam pass over an edge of the substrate W and are being directed into the cover ring 162. The substrate W then turns around and begins passing in an opposite direction, towards the second position. In some embodiments, a distance between the first and second positions is a whole number of periods of the beam blockers 166 and/or the apertures 168 (“slit pitch”).

In an ideal case, the substrate W scans at a constant speed and infinite acceleration at the turnaround points, and the whole substrate W is exposed to a uniform ion flux each half cycle. However, in practice, the substrate W will slow down at turnaround points, leading to higher local ion fluxes. To address this, the processing apparatus 101 of the present disclosure provides ramping acceleration with duty cycle correction. More specifically, the duty cycle decreases when the substrate W is nearing the first position and nearing the second position, and increases when the substrate W is moving between the first and second positions. With more realistic wafer acceleration profiles at turnaround points, the ion flux non-uniformity can reach approximately 50%. It has been determined that scaling the duty cycle by the velocity profile restores uniform ion beam flux at the substrate W. To reduce loss in productivity, it's desirable to scan slower, spending less time near the turnaround points.

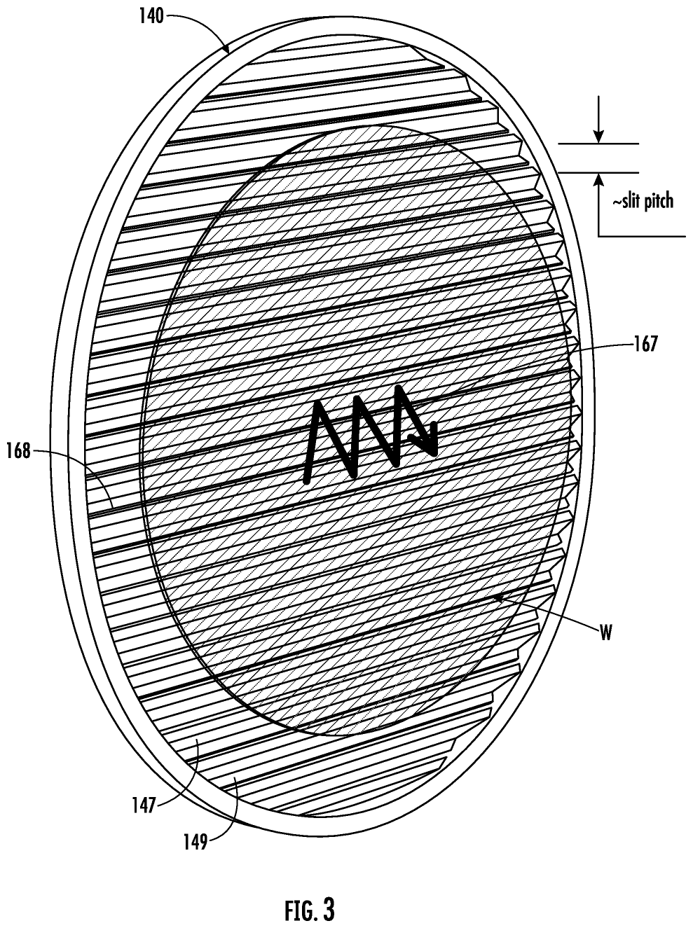

FIG. 3 further demonstrates dithering of the substrate W relative to the extraction plate 140. In this non-limiting embodiment, the extraction plate 140 has a series of parallel peaks 147 and valleys 149 arranged in an accordion configuration. Apertures 168 may be formed between each of the peaks 147 and valleys 149. Instead of using a small source or ribbon beam and scanning the wafer all the way through, as in some prior art approaches, embodiments herein allow for a relatively larger source together with a more limited dither scan. Advantageously, a smaller scan length can translate to a smaller process chamber, while the substrate W remaining in the beam means higher throughput (e.g., up to 17× effective current) and a more uniform wafer temperature and pressure. Furthermore, a smaller halo leads to less foreign material sputtering. During use, the substrate W may be scanned 167 only over a vertical range equal to the slit pitch times an integer.

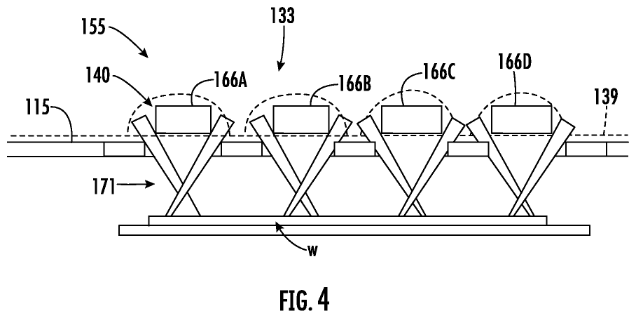

FIG. 4 represents one non-limiting embodiment of a portion of the ion extraction optics (hereinafter “optics”) 133 of the extraction assembly 155. The optics 133 may be arranged along the second end wall 115, and may include the extraction plate 140 having a plurality of beam blockers 166A-166D, arranged proximate apertures defined by the extraction plate 140. As shown, the beam blockers 166A-166D define extraction slits, wherein these extraction slits may generate different ribbon beams or ion beamlets 171 that impact the substrate W. By selective arrangement of the beam blockers 166A-166D of the extraction plate 140, mitigation of the difference in ion angular distributions of the ion beamlets extracted from the different extraction slits is possible. In an exemplary embodiment, the beam blockers 166A-166D and the extraction slits may be uniformly sized and spaced apart from one another. As a result, the different ribbon beams or ion beamlets 171 are uniform/symmetrical. It will be contemplated that the extraction plate 140 may include additional beam blockers and therefore additional extraction slits and ribbon beams. For example, 15-20 beam blockers operable to cover a distance of approximately 350 mm may be employed in some embodiments. It will be further contemplated that the beam blockers of the extraction plate 140 may be adjustable (e.g., rotatable) in alternative embodiments. Embodiments herein are not limited in this context, however.

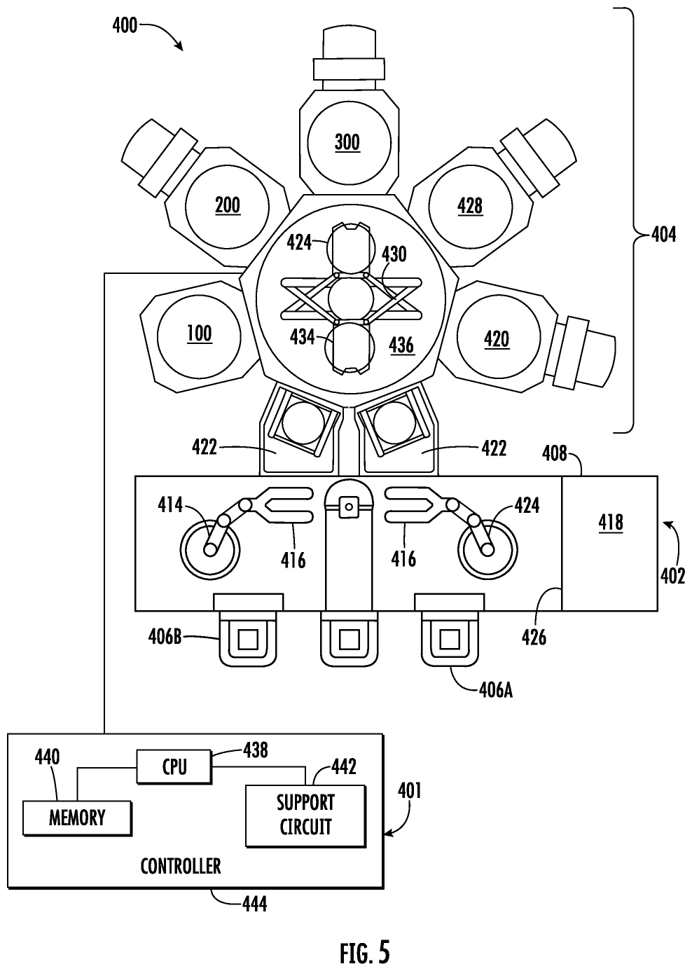

FIG. 5 is a schematic top plan view of an exemplary cluster processing system 400 that includes one or more of the processing chambers, such as the plasma processing chamber 100 described herein. In one embodiment, the cluster processing system 400 may be a CENTURA® or ENDURA® integrated processing system, commercially available from Applied Materials, Inc., located in Santa Clara, CA. It is contemplated that other processing systems (including those from other manufacturers) may be adapted to benefit from the disclosure.

The cluster processing system 400 may include a vacuum-tight processing platform 404, a factory interface 402, and a system controller 444. The platform 404 includes a plurality of processing chambers 100, 200, 300, 428, 420 and at least one load-lock chamber 422 that is coupled to a vacuum substrate transfer chamber 436. Two load lock chambers 422 are shown in FIG. 5. The factory interface 402 is coupled to the transfer chamber 436 by the load lock chambers 422.

In one embodiment, the factory interface 402 comprises at least one docking station 408 and at least one factory interface robot 414 to facilitate transfer of substrates. The docking station 408 is configured to accept one or more front opening unified pod (FOUP). Two FOUPS 406A-B are shown in the embodiment of FIG. 5. The factory interface robot 414 having a blade 416 disposed on one end of the robot 414 is configured to transfer the substrate from the factory interface 402 to the processing platform 404 for processing through the load lock chambers 422. Optionally, one or more metrology stations 418 may be connected to a terminal 426 of the factory interface 402 to facilitate measurement of the substrate from the FOUPS 406A-B.

Each of the load lock chambers 422 have a first port coupled to the factory interface 402 and a second port coupled to the transfer chamber 436. The load lock chambers 422 are coupled to a pressure control system (not shown) which pumps down and vents the load lock chambers 422 to facilitate passing the substrate between the vacuum environment of the transfer chamber 436 and the substantially ambient (e.g., atmospheric) environment of the factory interface 402.

The transfer chamber 436 has a vacuum robot 430 disposed therein. The vacuum robot 430 has a blade 434 capable of transferring substrates 424 among the load lock chambers 422, the metrology system 410 and the processing chambers 100, 200, 332, 428, 420.

In one embodiment of the cluster processing system 400, the cluster processing system 400 may include one or more processing chambers 100, 200, 300, 428, 420, which may be a deposition chamber (e.g., physical vapor deposition chamber, chemical vapor deposition, or other deposition chambers), annealing chamber (e.g., high pressure annealing chamber, RTP chamber, laser anneal chamber), etch chamber, cleaning chamber, curing chamber, lithographic exposure chamber, or other similar type of semiconductor processing chambers.

The system controller 444 is coupled to the cluster processing system 400. The system controller 444, which may include the computing device 401 or be included within the computing device 401, controls the operation of the cluster processing system 300 using a direct control of the processing chambers 100, 200, 300, 428, 420 of the cluster processing system 400. Alternatively, the system controller 444 may control the computers (or controllers) associated with the processing chambers 100, 200, 300, 428, 420 and the cluster processing system 400. In operation, the system controller 444 also enables data collection and feedback from the respective chambers to optimize performance of the cluster processing system 400.

The system controller 444, much like the computing device 401 described above, generally includes a central processing unit (CPU) 438, a memory 440, and support circuits 442. The CPU 438 may be one of any form of a general-purpose computer processor that can be used in an industrial setting. The support circuits 442 are conventionally coupled to the CPU 438 and may comprise cache, clock circuits, input/output subsystems, power supplies, and the like. The software routines transform the CPU 438 into a specific purpose computer (controller) 444. The software routines may also be stored and/or executed by a second controller (not shown) that is located remotely from the cluster processing system 400.

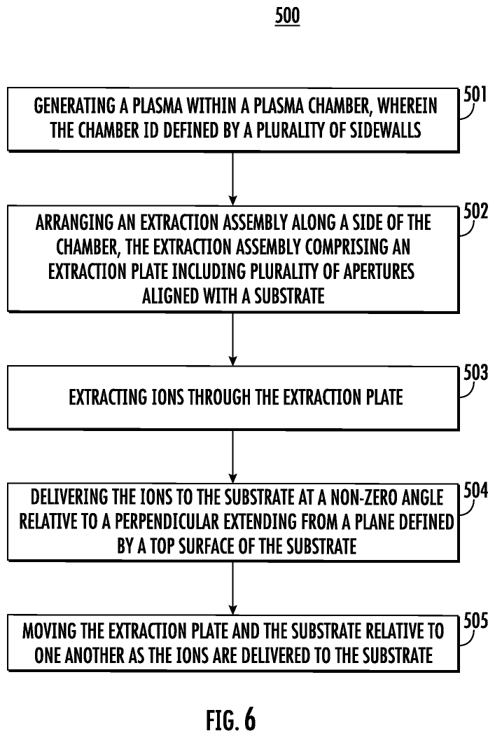

FIG. 6 depicts a flow diagram illustrating a process 500 for high-throughput angled ion processing according to embodiments of the present disclosure. At block 501, the process 500 may include generating a plasma within a plasma chamber, wherein the chamber is defined by a plurality of sidewalls, a first end wall, and a second end wall opposite the first end wall. In some non-limiting embodiments, the plasma processing chamber includes a chamber body having a chamber volume defined therein. The chamber body may be coupled to ground, and the sidewalls may have a liner to protect the sidewalls.

In some embodiments, generating the plasma may include energizing a process gas to form the plasma in the chamber using an RF coil, wherein the RF coil is positioned adjacent the plurality of sidewalls of the plasma chamber.

At block 502, the process 500 may include arranging an extraction assembly along a side of the chamber, such as the second end wall, wherein the extraction assembly includes an extraction plate having plurality of apertures aligned with the substrate. In some embodiments, each of the plurality of plates includes one or more straight portions. In some embodiments, the extraction assembly may include an extraction plate including a plurality of beam blockers. The beam blockers may define one or more extraction slits for ions to pass therethrough. In some embodiments, the extraction plate is directly attached or coupled to the sidewall(s) of the chamber.

At block 503, the process 500 may include extracting ions through the extraction plate.

At block 504, the process 500 may include delivering the ions to the substrate at a non-zero angle relative to a perpendicular extending from a plane defined by a top surface of the substrate. In some embodiments, the ions are delivered to the substrate to etch one or more areas of the substrate, and/or to etch one or more layers or features formed atop the substrate. In other embodiments, ions are delivered to the substrate to deposit a material atop the substrate (e.g., a liner layer, hardmask layer, etc.). During processing, the substrate W remains generally aligned with the extraction plate throughout an entirety of the scan cycle. Said another way, a perimeter of the substrate W remains within a projection of a perimeter of the extraction plate throughout the scan cycle. As a result, no large area for overscanning adjacent the substrate is needed.

At block 505, the process 500 may include dithering the substrate relative to the extraction plate as the ions are delivered to the substrate. In some embodiments, an actuator may be used to shift the platen and thus the substrate as the ions are extracted through the opening. In other embodiments, the plasma source may be pulsed or dithered while the extraction plate and the substrate are stationary. In some embodiments, the substrate is DC (e.g., pulsed DC) or RF biased as the ions are delivered to the substrate.

In some embodiments, a duty cycle is varied as the substrate is being dithered, wherein the duty cycle may be varied by varying the pulsed bias. In some embodiments, the power supply reduces the duty cycle when the substrate is in a first position and/or a second position. The first and second position represent turnaround points of the substrate. As the substrate moves between the first and second positions, the duty cycle may be increased.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A processing apparatus, comprising:
a chamber operable to contain a plasma, the chamber defined by a plurality of sidewalls, a first end wall, and a second end wall opposite the first end wall;
an extraction assembly coupled to the second end wall, the extraction assembly comprising a plurality of apertures positionable relative to a substrate, wherein ions are extracted through the plurality of apertures and delivered to the substrate at a non-zero angle relative to a perpendicular extending from the substrate, and wherein the substrate is positioned external to the chamber; and
an actuator operable to dither the substrate relative to the extraction assembly as the ions are extracted through the plurality of apertures.

2. The processing apparatus of claim 1, further comprising an RF coil to energize a process gas to form a plasma in the chamber.

3. The processing apparatus of claim 1, wherein the second end wall has an interior side opposite an exterior side, and wherein the substrate is positioned adjacent the exterior side.

4. The processing apparatus of claim 1, wherein the extraction assembly comprises an extraction plate comprising a plurality of beam blockers, wherein ion beamlets are extracted through the plurality of apertures, and wherein the plurality of apertures are defined by the plurality of beam blockers.

5. The processing apparatus of claim 4, wherein the first end wall, the second end wall, and the plurality of sidewalls are a dielectric material, and wherein the extraction plate is conductive.

6. The processing apparatus of claim 1, further comprising a power supply operable to provide a pulsed bias, wherein a duty cycle in response to the pulsed bias varies as the substrate is dithered relative to the extraction assembly as the ions are extracted through the plurality of apertures.

7. The processing apparatus of claim 6, wherein the pulsed bias is a pulsed DC bias or a pulsed RF bias.

8. The processing apparatus of claim 6, wherein the actuator is operable to dither the substrate repeatedly between a first position and a second position, and wherein the power supply reduces the duty cycle when the substrate is in the first position and the second position.

9. A plasma processing apparatus, comprising:
a plasma chamber operable to contain a plasma, the plasma chamber defined by a plurality of sidewalls, a first end wall, and a second end wall opposite the first end wall;
an extraction assembly coupled to the second end wall, the extraction assembly comprising an extraction plate partially covering an opening through the second end wall, wherein ions extracted through a plurality of apertures of the extraction plate are delivered to a substrate at a non-zero angle relative to a perpendicular extending from the substrate, and wherein the substrate is positioned external to the plasma chamber; and
an actuator operable to dither the substrate relative to the extraction plate as the ions are extracted through the plurality of apertures.

10. The plasma processing apparatus of claim 9, further comprising an RF coil to energize a process gas to form a plasma in the plasma chamber, wherein the RF coil is positioned adjacent the first end wall of the plasma chamber.

11. The plasma processing apparatus of claim 9, wherein the extraction plate comprises a plurality of beam blockers, and wherein ion beamlets are extracted through the plurality of beam blockers to process one or more areas of the substrate.

12. The plasma processing apparatus of claim 11, further comprising a power supply operable to provide a pulsed bias, wherein a duty cycle in response to the pulsed bias varies as the substrate is dithered relative to the extraction assembly as the ions are extracted through the opening.

13. The plasma processing apparatus of claim 12, wherein the pulsed bias is a pulsed DC bias or a pulsed RF bias.

14. The plasma processing apparatus of claim 12, wherein the actuator is operable to dither the substrate repeatedly between a first position and a second position, and wherein the power supply reduces the duty cycle when the substrate is in the first position and the second position.

15. A method, comprising:
generating a plasma within a plasma chamber, wherein the chamber is defined by a plurality of sidewalls, a first end wall, and a second end wall opposite the first end wall;
arranging an extraction assembly along the second end wall, the extraction assembly comprising an extraction plate including plurality of apertures positionable relative to a substrate;
extracting ions through the extraction plate;
delivering the ions to the substrate at a non-zero angle relative to a perpendicular extending from a plane defined by a top surface of the substrate, wherein the substrate is positioned external to the plasma chamber; and
dithering the substrate relative to the extraction plate as the ions are delivered to the substrate.

16. The method of claim 15, further comprising energize a process gas to form the plasma in the plasma chamber using an RF coil, wherein the RF coil is positioned adjacent the plurality of sidewalls of the plasma chamber.

17. The method of claim 15, wherein the substrate is dithered repeatedly between a first position and a second position, and wherein the extraction plate is stationary.

18. The method of claim 15, wherein a duty cycle of a pulsed bias varies as the substrate is dithered relative to the extraction assembly, and wherein the pulsed bias is a pulsed DC bias or a pulsed RF bias.

19. The method of claim 18, wherein the actuator is operable to dither the substrate repeatedly between a first position and a second position, wherein the duty cycle is reduced when the substrate is in the first position and the second position, and wherein the duty cycle is increased when the substrate is moving between the first position and the second position.

20. The method of claim 15, further comprising biasing the extraction plate to adjust the non-zero angle of the ions delivered to the substrate.
